(19) United States
(12) Patent Application Publication
(10) Pub. No.: US 2023/0140523 A1
(43) Pub. Date: May 4, 2023

(54) METHOD FOR GENERATING MAGNETIC RESONANCE IMAGE AND MAGNETIC RESONANCE IMAGING SYSTEM

(71) Applicant: GE Precision Healthcare LLC, Wauwatosa, WI (US)

(72) Inventors: Jialiang Ren, Beijing (CN); Jingjing Xia, Shanghai (CN); Zhoushe Zhao, Beijing (CN)

(21) Appl. No.: 17/974,298

(22) Filed: Oct. 26, 2022

(30) Foreign Application Priority Data
Oct. 29, 2021 (CN) 202111276479.8

(51) Int. Cl. G06T 11/00; G01R 33/50

(52) U.S. Cl. CPC G06T 11/005; G01R 33/50

(57) ABSTRACT

Provided in embodiments of the present invention are a method for generating a magnetic resonance image, a magnetic resonance imaging system, and a computer-readable storage medium. The method comprises: generating a plurality of quantitative maps on the basis of a raw image, the raw image being obtained by executing a magnetic resonance scan sequence, and the magnetic resonance scan sequence having a plurality of scan parameters; performing image conversion on the plurality of quantitative maps on the basis of the plurality of scan parameters to generate a first converted image and a second converted image; generating a fused image of the first converted image and the second converted image; and generating a plurality of quantitative weighted images on the basis of the fused image.

### CROSS REFERENCE

The present application claims priority and benefit of Chinese Patent Application No. 202111276479.8 filed on Oct. 29, 2021, which is incorporated herein by reference in its entirety.

### FIELD OF THE INVENTION

Embodiments disclosed in the present invention relate to medical imaging technologies, and more particularly to a method for generating a magnetic resonance image, a magnetic resonance imaging system, and a computer-readable storage medium.

### BACKGROUND OF THE INVENTION

Quantitative magnetic resonance imaging (qMRI) can measure parametric maps, including quantitative parameters such as proton density (PD) and relaxation times (T1, T2), of which weighted images (WIs) are often required to be obtained in magnetic resonance imaging diagnosis.

Different quantitative weighted images usually need to be separately acquired through different scan sequences. For example, different quantitative weighted images need to be obtained by performing separate quantitative weighted scan sequences. Therefore, when a plurality of different quantitative weighted images need to be obtained, magnetic resonance examination would often take more time. In addition, in order to obtain required quantitative weighted images, a doctor may need to manually select corresponding scan sequences, thus increasing operational complexity and mis-operations.

### BRIEF DESCRIPTION OF THE INVENTION

Provided in one aspect of the present invention is a method for generating a magnetic resonance image, including: generating a plurality of quantitative maps on the basis of a raw image, the raw image being obtained by executing a magnetic resonance scan sequence, the magnetic resonance scan sequence having a plurality of scan parameters; performing image conversion on the plurality of quantitative maps on the basis of the plurality of scan parameters to generate a first converted image and a second converted image; generating a fused image of the first converted image and the second converted image; and generating a plurality of quantitative weighted images on the basis of the fused image.

In another aspect, the generating a plurality of quantitative maps on the basis of a raw image includes: generating a plurality of quantitative maps by performing deep learning processing on the raw image on the basis of a first deep learning network.

In another aspect, the plurality of quantitative weighted images are generated by performing deep learning processing on the fused image on the basis of a second deep learning network.

In another aspect, the fused image is generated by performing channel concatenation on the first converted image and the second converted image.

In another aspect, the plurality of quantitative maps include a quantitative T1 map, a quantitative T2 map, and a quantitative PD map, and the plurality of quantitative weighted images include a T1 weighted image, a T2 weighted image, and a T2 weighted-fluid attenuated inversion recovery image.

In another aspect, the plurality of scan parameters include echo time, repetition time, and inversion recovery time.

In another aspect, the “performing image conversion on the plurality of quantitative maps on the basis of the plurality of scan parameters to generate a first converted image and a second converted image” includes: generating the first converted image on the basis of a first formula having the echo time and the plurality of quantitative maps as variables; and generating the second converted image on the basis of a second formula having the echo time, the repetition time, the inversion recovery time, and the plurality of quantitative maps as variables.

In another aspect, the raw image includes at least one of a real image, an imaginary image, and a modular image generated on the basis of the real image and the imaginary image.

Further provided in another aspect of the present invention is a magnetic resonance imaging system, including: a scanner and an image processing module, wherein the scanner is configured to execute a magnetic resonance scan sequence to generate a raw image, the magnetic resonance scan sequence having a plurality of scan parameters. The image processing module includes: a first processing unit, configured to generate a plurality of quantitative maps on the basis of the raw image; a conversion unit, configured to perform image conversion on the plurality of quantitative maps on the basis of the plurality of scan parameters to generate a first converted image and a second converted image. The image processing module further includes an image fusion unit, configured to generate a fused image of the first converted image and the second converted image; and a second processing unit, configured to generate a plurality of quantitative weighted images on the basis of the fused image.

In another aspect, the first processing unit is configured to perform deep learning processing on the raw image on the basis of a first deep learning network to generate the plurality of quantitative maps.

In another aspect, the second processing unit performs deep learning processing on the fused image on the basis of a second deep learning network to generate the plurality of quantitative weighted images.

In another aspect, the image fusion unit is configured to perform channel concatenation on the first converted image and the second converted image to generate the fused image.

In another aspect, the raw image is obtained by executing a synthesized magnetic resonance scan sequence.

Further provided in another aspect of the present invention is a magnetic resonance imaging system, including a scanner and an image processing module. The scanner is configured to execute a magnetic resonance scan sequence to generate a raw image, the magnetic resonance scan sequence having a plurality of scan parameters; the image processing module is configured to receive the raw image and perform the method for generating a magnetic resonance image according to the above aspect of the claims.

Further provided in another aspect of the present invention is a computer-readable storage medium, including a stored computer program, wherein the method according to any one of the aforementioned aspects is performed when the computer program is run.

It should be understood that the brief description above is provided to introduce, in simplified form, some concepts that will be further described in the detailed description. The brief description above is not meant to identify key or essential features of the claimed subject matter. The scope is defined uniquely by the claims that follow the detailed description. Furthermore, the claimed subject matter is not limited to implementations that solve any disadvantages noted above or in any section of the present disclosure.

### BRIEF DESCRIPTION OF THE DRAWINGS

The present invention will be better understood by reading the following description of non-limiting embodiments with reference to the accompanying drawings, where

FIG. 1 shows a flowchart of a method for generating a magnetic resonance image according to an embodiment of the present invention;

FIG. 2 shows a schematic example diagram of an image processing module for performing the method;

FIG. 3 shows a schematic structural diagram of a magnetic resonance imaging system according to an embodiment;

FIG. 4 shows examples of a real image as a raw image in an embodiment of the present invention;

FIG. 5 shows examples of an imaginary image as a raw image in an embodiment of the present invention;

FIG. 6 shows examples of a modular image as a raw image in an embodiment of the present invention, which is obtained on the basis of a real image and an imaginary image;

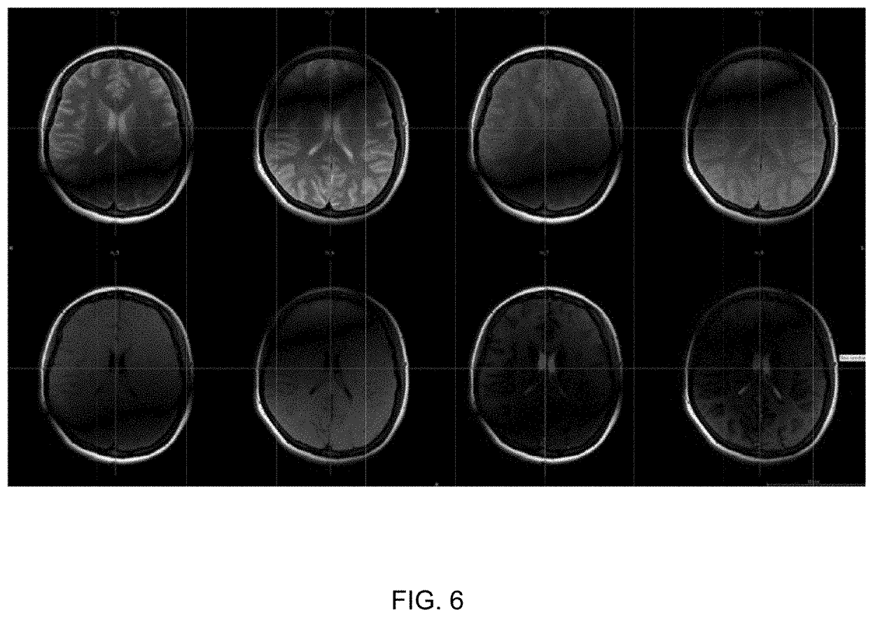

FIG. 7 shows a quantitative PD map, a quantitative T1 map, a quantitative T2 map, a T1WI, a T2WI, and a T2WI-FLAIR of the brain generated according to a conventional method;

FIG. 8 shows a quantitative PD map, a quantitative T1 map, a quantitative T2 map, a T1WI, a T2WI, and a T2WI-FLAIR of the brain generated according to an embodiment of the present invention; and

FIG. 9 shows a quantitative PD map, a quantitative T1 map, a quantitative T2 map, a T1WI, a T2WI, and a T2WI-FLAIR of a mammary gland tissue generated according to an embodiment of the present invention.

### DETAILED DESCRIPTION

Various embodiments described below include a method for generating a magnetic resonance image and a magnetic resonance imaging system, and a computer-readable storage medium.

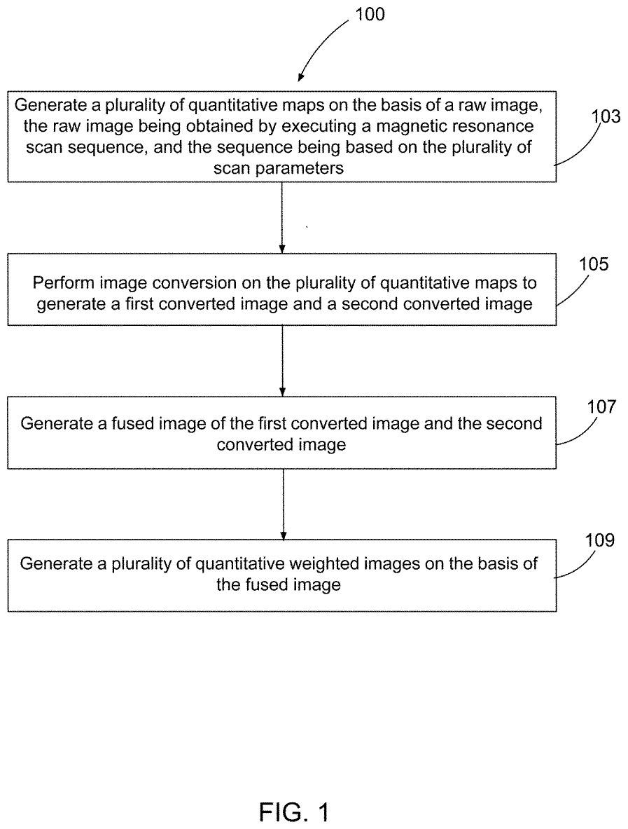

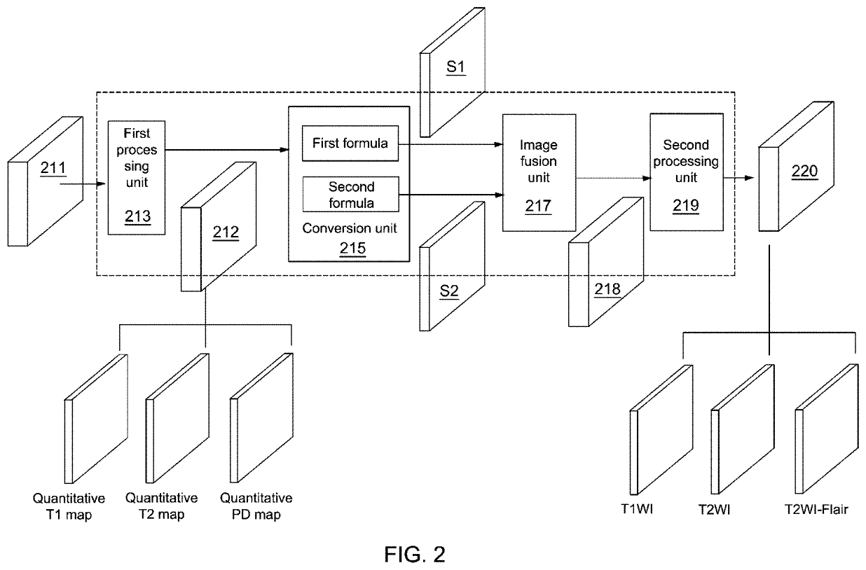

FIG. 1 shows a flowchart 100 of an embodiment of a method for generating a magnetic resonance image according to an embodiment of the present invention. FIG. 2 shows a schematic example diagram of an image processing module 200 for performing the method 100. Referring to FIG. 1 and FIG. 2 in combination, in step 103, a plurality of quantitative maps are generated on the basis of a raw image 211. The raw image 211 is obtained by executing a magnetic resonance scan sequence. The magnetic resonance scan sequence has a plurality of scan parameters, such as echo time (TE), repetition time (TR), and inversion recovery time (TI) as shown in FIG. 2.

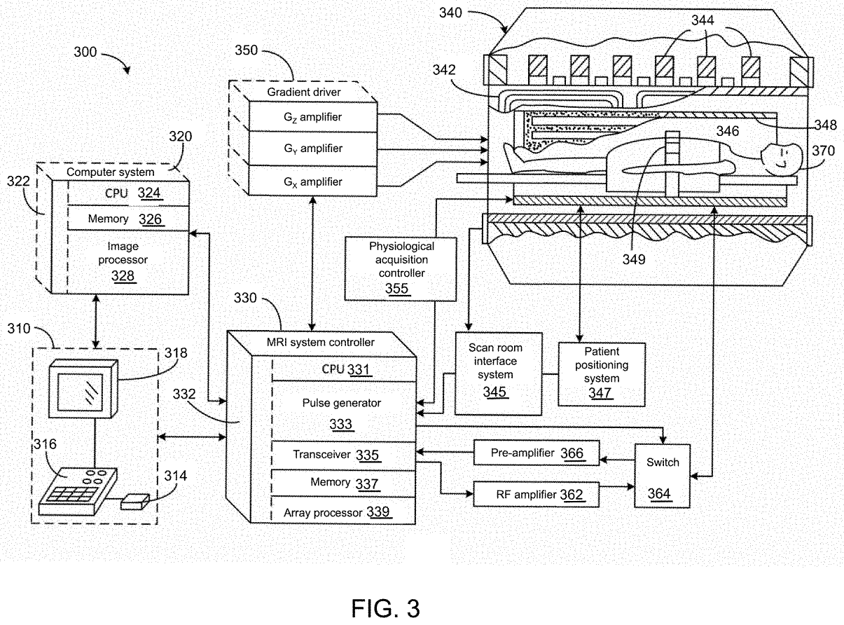

Techniques of executing a scan sequence and reconstructing a magnetic resonance image by a magnetic resonance imaging apparatus will be described below in conjunction with FIG. 3. The scan sequence executed in step 103 may be a two-dimensional (2D) fast spin echo (FSE) multiple delay multiple echo (MDME) sequence (or a synthesized magnetic resonance scan sequence (synthesized MRI)). In one example, the sequence includes interleaved slice-selective saturation RF pulses and multiple echo acquisitions. Using a 90° radio-frequency excitation pulse and a plurality of 180° pulses, a saturation is applied to slice n and an acquisition is applied to slice m. Slices n and m are different slices. Therefore, effective delay time between a saturation and an acquisition for each particular slice may be changed by selecting n and m. In some embodiments, a plurality of different selections of n and m are performed, resulting in a plurality of different delay times. Thus, a plurality of complex images with different contrasts of each slice may be reconstructed.

It should be understood that any suitable sequence other than MDME sequences may be used to generate raw images with different contrasts, for example, a combination of two or more sequences of spin echo (SE), FSE, gradient echo (GE), inversion recovery (IR), fast field echo (TFE) sequences, etc. may be employed.

Those skilled in the art understand that when the aforementioned scan sequence is applied to a tissue to be imaged, the length of time for a longitudinal magnetization vector of excited protons to return to a balanced state is longitudinal relaxation time (T1), and the length of time for a transverse magnetization vector to decay to 0 is transverse relaxation time (T2), and different tissues of the human body usually have different T1, T2, and proton densities (PDs). The aforementioned quantitative map may include a quantitative T1 map, a quantitative T2 map, and a quantitative PD map.

Among the weighted images acquired in the embodiment of the present invention, an image that highlights a T1 contrast between tissues is a T1-weighted image (T1WI), an image that highlights a T2 contrast between tissues is a T2-weighted image (T2WI), and an image that highlights a proton density contrast between tissues is a PD-weighted images (e.g., T2WI-Flair (fluid-attenuated inversion recovery)).

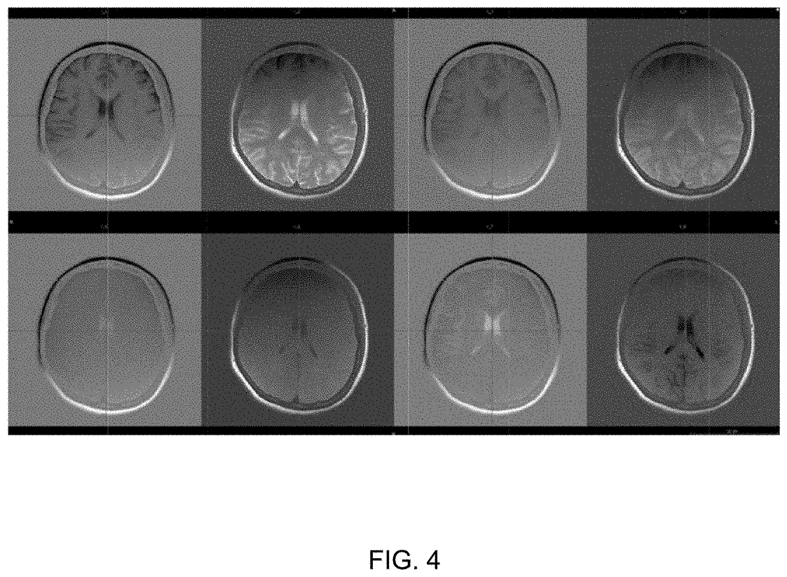

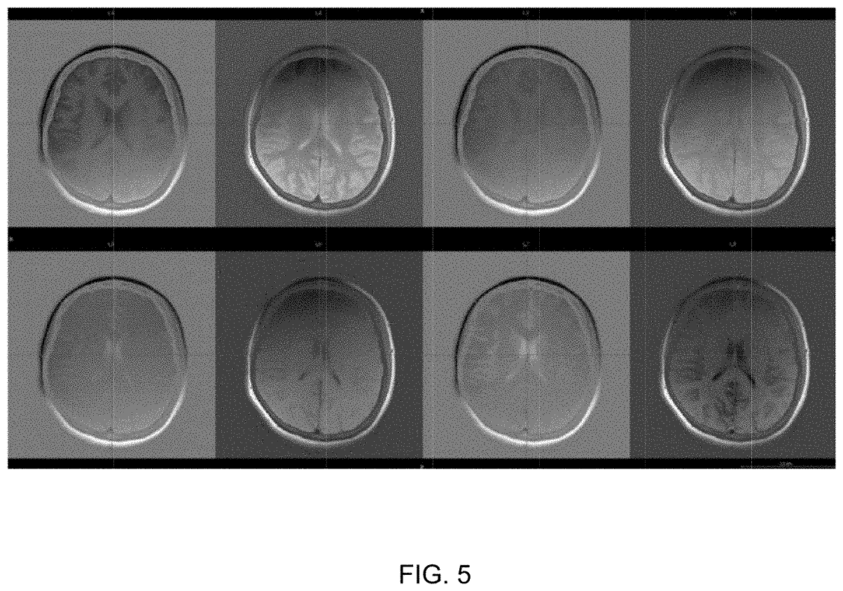

As an optional embodiment, the aforementioned raw image 211 may include a real image as shown in FIG. 4, an imaginary image as shown in FIG. 5, or a modular image, wherein the modular image is obtained by preprocessing the real image and the imaginary image. Specifically, the aforementioned preprocessing may be performed on the basis of the following formula.

M_{modular,i}=\sqrt{M_{real,i}²+M_{imaginary,i}²}

In the above formula, M_{real,i} is the i-th real image, M_{imaginary,i} is the i-th imaginary image, M_{modular,i} is the i-th modular image generated on the basis of the i-th real image and the i-th imaginary image, where i is the serial number of a plurality of contrast images obtained after the above scan sequence is executed.

When the modular image is used as a raw image to be processed, the generated quantitative map and quantitative weighted map have better image quality.

In step 103, specifically, deep learning processing may be performed on the aforementioned raw image 211 on the basis of a first deep learning network to generate the plurality of quantitative maps 212. For example, the trained first deep learning network 213 is used to receive the inputted raw image 211, and output a quantitative T1 map, a quantitative T2 map, a quantitative PD map, etc. as shown in FIG. 2.

When the first deep learning network is trained, an input data set may be a plurality of raw images generated by executing the scan sequence on a single part of the human body (such as the brain, abdomen) or a plurality of parts by using a scanner of a magnetic resonance imaging system, and an output data set may be a quantitative map calculated on the basis of each raw image, for example, a quantitative feature value of a corresponding voxel is calculated on the basis of a signal value of each pixel in each raw image of the input data set and a scan parameter used in the corresponding scan sequence, and the distribution of the quantitative feature value on the image forms a quantitative map of the feature. Therefore, a plurality of corresponding quantitative maps in the output data set may be obtained on the basis of each raw image in the input data set.

In other embodiments, the raw image in the input data set and the quantitative map in the output data set of the first deep learning network may not have the aforementioned correlation. For example, the quantitative map in the output data set may not be obtained via calculation on the raw image in the input data set. In sum, the output data set of the first neural network may be obtained using any known technique.

In the embodiment of the present invention, the plurality of quantitative maps outputted by the first neural network and the related scan parameters (TE, TR, and TI as shown in FIG. 2) when the corresponding scan sequence is executed may be stored in a storage space of the magnetic resonance imaging system, so as to be further invoked to implement the embodiment of the present invention.

Step 103 may be performed by the first processing unit 213 in FIG. 2, wherein the first deep learning network may be integrated in the first processing unit 213.

In step 105, image conversion is performed on the plurality of quantitative maps on the basis of the plurality of scan parameters to generate a first converted image S1 and a second converted image S2. In one embodiment, the first converted image S1 and the second converted image S2 may be generated on the basis of a first formula and a second formula, respectively, where the parameter TE and the plurality of quantitative maps are variables; the second formula uses the parameters TE, TR, and TI, and the plurality of quantitative maps as variables.

An example of this first formula may be:

S1=PD·exp(−TE/T2)·(1−exp(−TR/T1)), (1);

where S1 is the first converted image (or the distribution of magnetic resonance signal values in the image), exp is an exponential function with the natural constant e as a base, TE is the echo time, TR is the repetition time, and T1, T2, and PD are a quantitative T1 value, a quantitative T2 value, and a quantitative proton density value, respectively.

When the TE value and the TR value in the executed scan sequence are small, the obtained first converted image has characteristics more similar to those of a T1WI, for example, a water-containing tissue region such as cerebrospinal fluid is a dark region. When the TE value and the TR value of the scan sequence are large, the obtained first converted image has closer characteristics to those of a T2WI, for example, the water-containing tissue region such as cerebrospinal fluid is a bright region. When the TE value of the scan sequence is small and the TR value is large, the obtained first converted image has closer characteristics to those of a PDWI, for example, a tissue with more hydrogen proton content has a stronger image signal.

An example of the second formula may be:

S2=PD·exp(−TE/T2)·(1−2·exp(−TI/T1)+exp(−TR/T1), (2);

where S2 is the second converted image, exp is an exponential function with the natural constant e as a base, TE is the echo time, TR is the repetition time, and TI is the inversion recovery time.

When the TE value and the TR value in the executed scan sequence are small, and the TI value is small or moderate, the obtained second converted image has closer characteristics to those of a T1W-Flair. When the TE value, the TR value, and the TI value of the scan sequence are large, the obtained second converted image has closer characteristics to those of a T2W-Flair.

For a synthesized MM scan sequence, since the scan sequence is a multi-echo sequence, one sequence has a plurality of TEs, and each TE corresponds to a contrast image, then a plurality of first images and second images are also generated on the basis of the aforementioned first formula and second formula, respectively. The plurality of first images may be subjected to data fusion (e.g., channel concatenation) to form the first converted image S1, and the plurality of second images may be subjected to data fusion to form the second converted image S2.

Step 105 may be performed by a conversion unit 215 in FIG. 2. Specifically, the conversion unit 215 includes a first subunit for executing the first formula and a second subunit for executing the second formula.

In step 107, a fused image 218 of the first converted image S1 and the second converted image S2 is generated. In the embodiment of the present invention, the fused image 218 is generated by performing channel concatenation on the first converted image S1 and the second converted image S2. Therefore, original image information of the first converted image S1 and the second converted image S2 are not lost in the fused image 218, which is beneficial to obtaining a weighted image having closer characteristics to those of the actual tissue when further image processing is performed on the fused image 218. Step 107 may be performed by an image fusion unit 217 in FIG. 2.

In step 109, a plurality of quantitative weighted images are generated on the basis of the fused image 218. In one embodiment, deep learning processing is performed on the fused image on the basis of a second deep learning network to generate the plurality of quantitative weighted images. For example, the trained second deep learning network is used to receive the input fused image, and output the plurality of quantitative weighted images 220, such as the T1WI, the T2WI, and the T2WI-Flair in FIG. 2. The present disclosure only uses the above three quantitative weighted images as examples for description. Those skilled in the art would understand that in practical applications, more weighted images, for example, one or more of T1W-Flair, STIR (short T1 inversion recovery), PSIR (phase sensitive inversion recovery), and PSIR vossel, etc., may be generated on the basis of the second deep learning network.

Step 109 may be performed by a second processing unit 219 in FIG. 2, wherein the second processing unit 219 may be integrated with the second deep learning network.

When training the second deep learning network, an input data set may be a fusion data set of two or more quantitative weighted images synthesized on the basis of quantitative T1 maps, quantitative T2 maps, and quantitative PD maps. Moreover, any intermediate data (such as the quantitative T1 maps, the quantitative T2 maps, the quantitative PD maps, and quantitative weighted images synthesized based on these quantitative maps) in the process of obtaining the fused data may be obtained by performing step 103, 105, or 107 of the present invention, or may be obtained using other methods. An output data set of the second deep learning network may be a quantitative weighted image set obtained by an existing quantitative weighted imaging method (e.g., a quantitative weighted image set obtained by executing a different scan sequence from that in the embodiment of the present invention, or obtained by a more complex and time-consuming processing method).

In the embodiment of the present invention, the first deep learning network and the second deep learning network may be connected (for example, through the conversion unit 215 and the image fusion unit 217) to form an overall processing model, and when the processing model is trained with data, an input data set may be a collection of raw images generated by executing the aforementioned scan sequence on a single part or a plurality of parts of the human body by using the scanner of the magnetic resonance imaging system, and an output data set may be a collection of quantitative weighted images obtained by using existing methods.

The processing model may be trained using a training method having several steps, for example, one of the first deep learning network and the second deep learning network is fixed first, and only model parameters of the other network are updated until the parameters converge, and then the other network is fixed, and parameters of the first learning network are trained until convergence.

As discussed herein, the deep learning technology (also referred to as deep machine learning, hierarchical learning, deep structured learning, etc.) can employ an artificial neural network which performs leaning processing on input data. The deep learning method is characterized by using one or a plurality of network architectures to extract or simulate data of interest. The deep learning method may be implemented using one or a plurality of layers (such as an input layer, a normalization layer, a convolutional layer, and an output layer, where different deep learning network models may have different number or functions of layers), where the configuration and number of the layers allow the deep learning network to process complex information extraction and modeling tasks. Specific parameters (or referred to as “weight” or “bias”) of the network are usually estimated through a so-called learning process (or training process). The learned or trained parameters usually result in (or output) a network corresponding to layers of different levels, so that extraction or simulation of different aspects of initial data or the output of a previous layer usually may represent the hierarchical structure or concatenation of layers. During image processing or reconstruction, this may be represented as different layers with respect to different feature levels in the data. Thus, processing may be performed layer by layer. That is, “simple” features may be extracted from input data for an earlier or higher-level layer, and then these simple features are combined into a layer exhibiting features of higher complexity. In practice, each layer (or more specifically, each “neuron” in each layer) may process input data as output data for representation using one or a plurality of linear and/or non-linear transformations (so-called activation functions). The number of the plurality of “neurons” may be constant among the plurality of layers or may vary from layer to layer.

As discussed herein, as part of initial training of a deep learning process for solving a specific problem, a training data set includes a known input value and an expected (target) output value finally outputted from the deep learning process. In this manner, a deep learning algorithm can process the training data set (in a supervised or guided manner or an unsupervised or unguided manner) until a mathematical relationship between a known input and an expected output is identified and/or a mathematical relationship between the input and output of each layer is identified and represented. In the learning process, (part of) input data is usually used, and a network output is created for the input data. Afterwards, the created network output is compared with the expected output of the data set, and then a difference between the created and expected outputs is used to iteratively update network parameters (weight and/or bias). A stochastic gradient descent (SGD) method may usually be used to update network parameters. However, those skilled in the art should understand that other methods known in the art may also be used to update network parameters. Similarly, a separate validation data set may be used to validate a trained network, where both a known input and an expected output are known. The known input is provided to the trained network so that a network output can be obtained, and then the network output is compared with the (known) expected output to validate prior training and/or prevent excessive training.

Specifically, the first deep learning network and the second deep learning network may be obtained by training on the basis of an ADAM (adaptive moment estimation) optimization method or other well-known models. After the deep learning network is created or trained, a plurality of quantitative maps may be obtained (e.g., generated and outputted by the first deep learning network) by inputting a raw image obtained by executing a scan sequence into the processing model, and a plurality of quantitative weighted images that are closer to an actual tissue image are acquired at the same time (e.g., generated and outputted by the second deep learning network).

The first deep learning network and the second deep learning network may each include an input layer, an output layer, and a processing layer (or referred to as an intermediate layer), wherein the input layer is used to preprocess inputted data or images, for example, de-averaging, normalization, or dimensionality reduction, etc., and the processing layer may include a plurality of convolutional layers for feature extraction and an excitation layer for performing a nonlinear mapping on an output result of the convolutional layer using an activation function.

In the embodiment of the present invention, the activation function may be Relu (rectified linear units), and for the input layer and each intermediate layer, before the activation function is used for mapping, input data of the layer may be subjected to batch normalization (BN) processing to reduce the difference of range between samples, thereby avoiding the loss of gradients, reducing the dependence of gradients on parameters or initial values, thereby accelerating convergence.

Each convolutional layer includes several neurons, and the numbers of neurons in the plurality of convolutional layers may be the same or may be set differently as required. On the basis of a known input (such as a raw image) and expected output (such as a plurality of ideal, differently quantitative weighted images), the number of processing layers in the network and the number of neurons in each processing layer are set, and network parameters are estimated (or adjusted or calibrated), so as to identify a mathematical relationship between the known input and the expected output and/or identify and characterize a mathematical relationship between the input and output of each layer.

Specifically, when the number of neurons in one of the layers is n, and values corresponding to the n neurons are X₁, X₂, . . . , and Xₙ, the number of neurons in a next layer connected to the layer is m, and values corresponding to the m neurons are Y₁, Y₂, . . . , and Yₘ, the two adjacent layers may be represented as:

$${Y}_{j} = f ( {\sum }_{i = 1}^{n} {W}_{ji} {X}_{i} + {B}_{j} )$$

where Xᵢ represents a value corresponding to the i-th neuron of a previous layer, Yⱼ represents a value corresponding to the j-th neuron of a next layer, Wⱼᵢ represents a weight, and Bⱼ represents a bias. In some embodiments, the function f is a rectified linear function.

Thus, by adjusting the weight Wⱼᵢ and/or the bias Bⱼ, the mathematical relationship between the input and output of each layer can be identified, so that a loss function converges, so as to obtain the aforementioned deep learning network through training.

In this embodiment, network parameters of the deep learning network are obtained by solving the following formula (3):

min θ∥f(θ)−f∥2, (3)

where θ represents a network parameter of the deep learning network, which may include the aforementioned weight Wⱼᵢ and/or bias Bⱼ, f includes a known quantitative weighted image, f(θ) represents an output of the deep learning network, and min represents minimization. The network parameters are set by minimizing the difference between a network output image and an actual scanned image to construct the deep learning network.

In the embodiment of the present invention, an input of each convolutional layer includes data of all previous layers. For example, after an output of each layer preceding a current layer is subjected to channel concatenation, a convolution operation is performed on the current layer, thereby improving the efficiency of network training.

In one embodiment, although the configuration of the deep learning network is guided by dimensions such as prior knowledge, input, and output of an estimation problem, optimal approximation of required output data is implemented depending on or exclusively according to input data. In various alternative implementations, clear meaning may be assigned to some data representations in the deep learning network using some aspects and/or features of data, an imaging geometry, a reconstruction algorithm, or the like, which helps to speed up training. This creates an opportunity to separately train (or pre-train) or define some layers in the deep learning network.

In some embodiments, the aforementioned trained network is obtained based on training by a training module on an external carrier (for example, a device outside the medical imaging system). In some embodiments, the training system may include a first module configured to store a training data set, a second module configured to perform training and/or update based on a model, and a communication network configured to connect the first module and the second module. In some embodiments, the first module includes a data transmission unit and a first storage unit, where the first storage unit is configured to store a training data set, and the data transmission unit is configured to receive a relevant instruction (for example, for acquiring the training data set) and send the training data set according to the instruction. In addition, the second module includes a model update unit and a second storage unit, where the second storage unit is configured to store a training model, and the model update unit is configured to receive a relevant instruction and perform training and/or update of the network, etc. In some other embodiments, the training data set may further be stored in the second storage unit of the second module, and the training system may not include the first module. In some embodiments, the communication network may include various connection types, such as wired or wireless communication links, or fiber-optic cables.

Once data (for example, a trained network) is generated and/or configured, the data can be replicated and/or loaded into the medical imaging system (for example, the magnetic resonance imaging system that will be described below), which may be accomplished in a different manner. For example, a model may be loaded via a directional connection or link between the medical imaging system and a computer. In this regard, communication between different elements may be accomplished using an available wired and/or wireless connection and/or based on any suitable communication (and/or network) standard or protocol. Alternatively or additionally, the data may be indirectly loaded into the medical imaging system. For example, the data may be stored in a suitable machine-readable medium (for example, a flash memory card), and then the medium is used to load the data into the medical imaging system (for example, by a user or an authorized person of the system on site); or the data may be downloaded to an electronic device (for example, a laptop computer) capable of local communication, and then the device is used on site (for example, by a user or an authorized person of the system) to upload the data to the medical imaging system via a direct connection (for example, a USB connector).

Referring to FIG. 3, a schematic diagram of an exemplary MRI (magnetic resonance imaging) system 300 according to some embodiments is shown. As an example, the system 300 may be used to execute a scan sequence to generate the aforementioned initial image, and may also be used to store or transfer the generated image to other systems. The MM system 300 includes a scanner 340 of which an operation may be controlled via an operator workstation 310 that includes an input device 314, a control panel 316, and a display 318. The input device 314 may be a joystick, a keyboard, a mouse, a trackball, a touch-activated screen, a voice control, or any similar or equivalent input device. The control panel 316 may include a keyboard, a touch-activated screen, a voice control, a button, a slider, or any similar or equivalent control device. The operator workstation 310 is coupled to and in communication with a computer system 320 that enables an operator to control generation and display of images on the display 318. The computer system 320 includes various components that communicate with each other via an electrical and/or data connection module 322. The connection module 322 may be a direct wired connection, a fiber optic connection, a wireless communication link, etc. The computer system 320 may include a central processing unit (CPU) 324, a memory 326, and an image processor 328. In some embodiments, the image processor 328 may be replaced by image processing functions implemented in a CPU 324. The computer system 320 may be connected to an archival media device, a persistent or backup storage, or a network. The computer system 320 may be coupled to and in communication with a separate MRI system controller 330.

Part or all of the image processing module 200 for performing the method for generating a magnetic resonance image according to the embodiments of the present invention may be integrated in the computer system 320, for example, may be specifically provided in the image processor 328. However, the aforementioned image processing module may also be separate from the image processor 328 or the computer system 320.

The MRI system controller 330 includes a set of components that communicate with each other via an electrical and/or data connection module 332. The connection module 332 may be a direct wired connection, a fiber optic connection, a wireless communication link, etc. The MM system controller 330 may include a CPU 331, a sequence pulse generator 333 in communication with the operator workstation 310, a transceiver (or an RF transceiver) 335, a memory 337, and an array processor 339. In some embodiments, the sequence pulse generator 333 may be integrated into the scanner 340 of the MRI system 300. The MRI system controller 330 may receive commands from the operator workstation 310 to indicate an MRI scan sequence to be executed during an MRI scan, and the pulse sequence generator 333 generates the scan sequence on the basis of the indication. The MRI system controller 30 is further coupled to and in communication with a gradient driver system 350, which is coupled to a gradient coil assembly 342 to generate a magnetic field gradient during the MRI scan.

The “scan sequence” refers to a combination of pulses having specific amplitudes, widths, directions, and time sequences and applied when a magnetic resonance imaging scan is executed. The pulses may typically include, for example, a radio-frequency pulse and a gradient pulse. The radio-frequency pulses may include, for example, radio-frequency excitation pulses, radio-frequency refocus pulses, inverse recovery pulses, etc. The gradient pulses may include, for example, the aforementioned gradient pulse used for layer selection, gradient pulse used for phase encoding, gradient pulse used for frequency encoding, gradient pulse used for phase offset (phase shift)/inversion/inversion recovery, gradient pulse used for discrete phase (phase dispersion), etc. The scan sequence may be, for example, the aforementioned MDME sequence.

The sequence pulse generator 333 may further receive data from a physiological acquisition controller 355, which receives signals from a number of different sensors, such as electrocardiogram (ECG) signals from electrodes attached to a patient, which are connected to the subject or patient 370 undergoing an MRI scan. The sequence pulse generator 333 is coupled to and in communication with a scan room interface system 345 that receives signals from various sensors associated with the state of the scanner 340. The scan room interface system 345 is further coupled to and in communication with a patient positioning system 347 that sends and receives signals to control movement of a patient table to a desired position to perform the MRI scan.

The MRI system controller 330 provides gradient waveforms (e.g., generated via the sequence pulse generator 333) to the gradient driver system 350, and the gradient driver system 350 includes Gₓ, G_{y}, and G_{z} amplifiers, etc. Each Gₓ, G_{y}, and G_{z} gradient amplifier excites a corresponding gradient coil in the gradient coil assembly 342 so as to generate a magnetic field gradient used to spatially encode an MR signal during the MM scan. The gradient coil assembly 342 is disposed within the scanner 340, and the resonance assembly further includes a superconducting magnet having a superconducting coil 344 that, in operation, provides a static uniform longitudinal magnetic field Bo throughout a cylindrical imaging volume 346. When a part to be imaged of the human body is positioned in Bo, nuclear spin associated with atomic nuclei in human tissues is polarized, so that a tissue of the part to be imaged generates a longitudinal magnetization vector at a macroscopic level, which is in a balanced state. The scanner 340 further includes an RF body coil 348, which, in operation, provides a lateral radio frequency field Bi that is substantially perpendicular to Bo throughout the cylindrical imaging volume 346. After the frequency field Bi field is applied, the direction of rotation of protons changes, the longitudinal magnetization vector decays, and the tissue of the part to be imaged generates a transverse magnetization vector at a macroscopic level.

After the radio-frequency field Bi is removed, the longitudinal magnetization strength is gradually restored to the balanced state, the transverse magnetization vector decays in a spiral manner until the vector is restored to zero. A magnetic resonance signal is generated during the restoration of the longitudinal magnetization vector and the decay of the transverse magnetization vector. The magnetic resonance signal can be acquired, and a tissue image of the part to be imaged can be reconstructed on the basis of the acquired signal.

The scanner 340 may further include an RF surface coil 349 for imaging different anatomical structures of the patient undergoing the MRI scan. The RF body coil 348 and the RF surface coil 349 may be configured to operate in a transmit and receive mode, a transmit mode, or a receive mode.

The subject or patient 370 of the MRI scan may be positioned within the cylindrical imaging volume 346 of the scanner 340. A transceiver 335 in the MRI system controller 330 generates RF excitation pulses that are amplified by an RF amplifier 362 and provided to the RF body coil 348 through a transmit/receive switch (T/R switch) 364.

As described above, the RF body coil 348 and the RF surface coil 349 may be used to transmit RF excitation pulses and/or receive resulting MR signals from the patient undergoing the MM scan. The MR signals emitted by excited nuclei in the patient of the MRI scan may be sensed and received by the RF body coil 348 or the RF surface coil 349 and sent back to a preamplifier 366 through the T/R switch 364. The T/R switch 364 may be controlled by a signal from the sequence pulse generator 333 to electrically connect the RF amplifier 362 to the RF body coil 348 in the transmit mode and to connect the preamplifier 366 to the RF body coil 348 in the receive mode. The T/R switch 364 may further enable the RF surface coil 349 to be used in the transmit mode or the receive mode.

In some embodiments, the MR signals sensed and received by the RF body coil 348 or the RF surface coil 349 and amplified by the preamplifier 366 are stored in a memory 337 for post-processing as a raw k-space data array. A reconstructed magnetic resonance image may be obtained by transforming/processing the stored raw k-space data.

In some embodiments, the MR signals sensed and received by the RF body coil 348 or the RF surface coil 349 and amplified by the preamplifier 366 are demodulated, filtered, and digitized in a receiving portion of transceiver 335, and transmitted to the memory 337 in the MRI system controller 330. For each image to be reconstructed, the data is rearranged into separate k-space data arrays, and each of these separate k-space data arrays is inputted to the array processor 339, which is operated to convert the data into an array of image data by Fourier transform.

The array processor 339 uses transform methods, most commonly Fourier transform, to create images from the received MR signals. These images are transmitted to the computer system 320 and stored in the memory 326. In response to commands received from the operator workstation 310, the image data may be stored in a long-term storage, or may be further processed by the image processor 328 and transmitted to the operator workstation 310 for presentation on the display 318.

In various embodiments, components of the computer system 320 and the MRI system controller 330 may be implemented on the same computer system or on a plurality of computer systems. It should be understood that the MM system 300 shown in FIG. 3 is intended for illustration. Suitable MM systems may include more, fewer, and/or different components.

The MRI system controller 330 and the image processor 328 may separately or collectively include a computer processor and a storage medium. The storage medium records a predetermined data processing program to be executed by the computer processor. For example, the storage medium may store a program used to implement scanning processing (such as a scan flow and an imaging sequence), image reconstruction, image processing, etc. For example, the storage medium may store a program used to implement the method for generating a magnetic resonance image according to the embodiments of the present invention. The storage medium may include, for example, a ROM, a floppy disk, a hard disk, an optical disk, a magneto-optical disk, a CD-ROM, or a non-volatile memory card.

On the basis of the above description, an embodiment of the present invention may further provide a magnetic resonance imaging system, which includes a scanner and an image processing module. An example of the scanner may be the scanner 340 in FIG. 2, and an example of the image processing module is shown in FIG. 2. The scanner is used for executing a magnetic resonance scan sequence to generate a raw image, and the magnetic resonance scan sequence has a plurality of scan parameters. The image processing module includes a first processing unit, a conversion unit, an image fusion unit, and a second processing unit. The first processing unit is configured to generate a plurality of quantitative maps on the basis of the raw image, the conversion unit is configured to perform image conversion on the plurality of quantitative maps on the basis of the plurality of scan parameters to generate a first converted image and a second converted image, and the image fusion unit is configured to generate a fused image of the first converted image and the second converted image; the second processing unit is configured to generate a plurality of quantitative weighted images on the basis of the fused image.

Further, the first processing unit is configured to perform deep learning processing on the raw image on the basis of a first deep learning network to generate the plurality of quantitative maps.

Further, the second processing unit performs deep learning processing on the fused image on the basis of a second deep learning network to generate the plurality of quantitative weighted images.

Further, the second processing unit performs deep learning processing on the fused image on the basis of the second deep learning network to generate the plurality of quantitative weighted images.

Further, the image fusion unit is configured to perform channel concatenation on the first converted image and the second converted image to generate the fused image.

On the basis of the above description, an embodiment of the present invention may further provide a magnetic resonance imaging system, which includes a scanner and an image processing module. An example of the scanner may be the scanner 340 in FIG. 2, and an example of the image processing module is shown in FIG. 2. The scanner is configured to execute a magnetic resonance scan sequence to generate a raw image, the magnetic resonance scan sequence having a plurality of scan parameters, and the image processing module is configured to receive the raw image and perform the method for generating a magnetic resonance image according to any embodiment of the present invention.

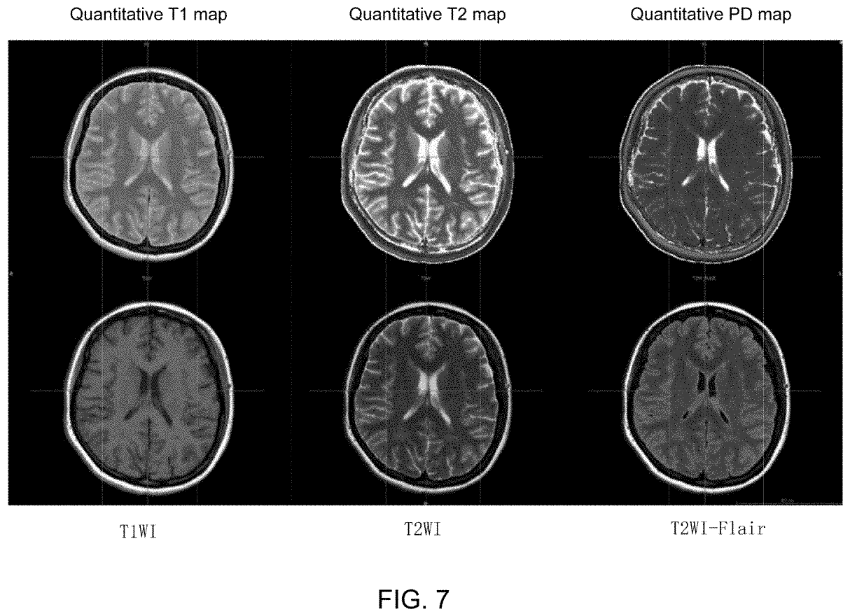

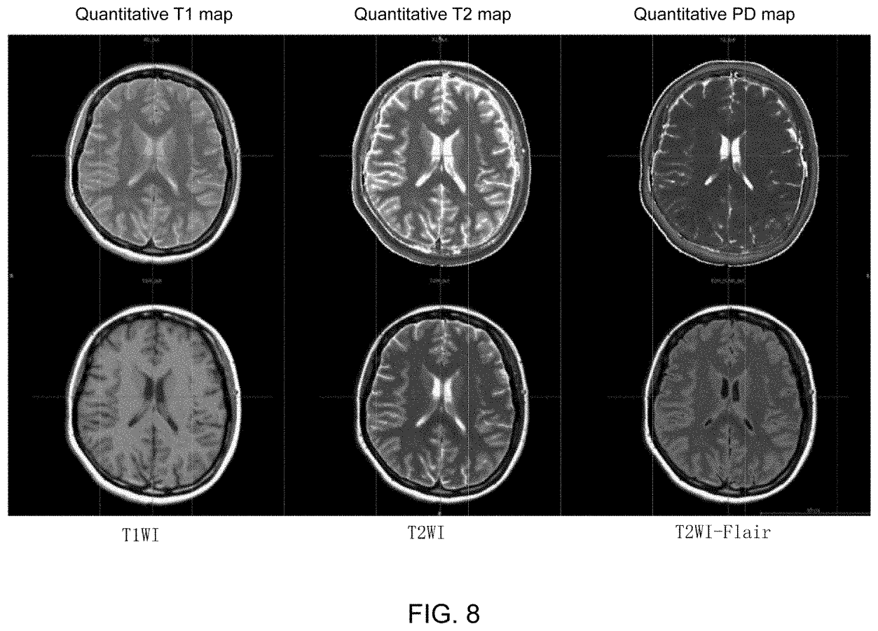

FIG. 7 shows a quantitative PD map, a quantitative T1 map, a quantitative T2 map, a T1WI, a T2WI, and a T2WI-FLAIR of the brain obtained using a conventional method. FIG. 8 shows a quantitative PD map, a quantitative T1 map, a quantitative T2 map, a T1WI, a T2WI, and a T2WI-FLAIR of the brain obtained using an embodiment of the present invention. Comparing FIG. 7 and FIG. 8, it can be seen that the images generated using the embodiment of the present invention have similar or improved image quality, and the embodiment of the present invention can simultaneously generate a plurality of quantitative maps and quantitative weighted images more quickly, and greatly reduce operational complexity, for example, there is no need to select a corresponding image processing channel for each quantitative weighted image.

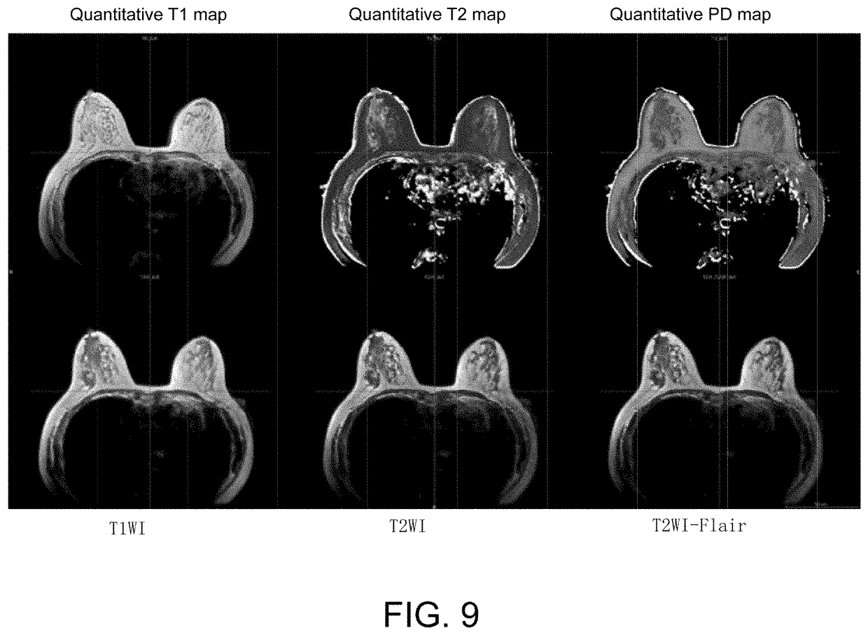

FIG. 9 shows a quantitative PD map, a quantitative T1 map, a quantitative T2 map, a T1WI, a T2WI, and a T2WI-FLAIR of a mammary gland tissue obtained using an embodiment of the present invention. Although a deep learning training data set selected in the embodiment of the present invention does not include images of the mammary gland tissue, the mammary gland tissue images generated on the basis of such a processing model still have similar or improved image quality to images obtained in a conventional manner.

In various embodiments above, the modules and units include a circuit that is configured to execute one or a plurality of tasks, functions, or steps discussed herein. In various embodiments, a part or the entirety of the processing module 200 may be integrated with the image processing module 320 or the operator workstation 310 of the magnetic resonance imaging system. The “processing module” and “processing unit” used herein are not intended to necessarily be limited to a single processor or computer. For example, the processing unit includes a plurality of processors, ASICs, FPGAs, and/or computers, and the plurality of processors, ASICs, FPGAs, and/or computers may be integrated in a common casing or unit, or may be distributed among various units or casings. The depicted processing units and processing modules include a memory. The memory 130 may include one or a plurality of computer-readable storage media. For example, the memory may store algorithms for implementing any of the embodiments of the present invention.

As used herein, an element or step described as singular and preceded by the word “a” or “an” should be understood as not excluding such element or step being plural, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional elements that do not have such property. The terms “including” and “in which” are used as the plain-language equivalents of the respective terms “comprising” and “wherein.” Furthermore, in the appended claims, the terms “first”, “second,” “third” and so on are used merely as labels, and are not intended to impose numerical requirements or a particular positional order on their objects.

This written description uses examples to disclose the present invention, including the best mode, and also to enable those of ordinary skill in the relevant art to implement the present invention, including making and using any devices or systems and performing any incorporated methods. The patentable scope of the present invention is defined by the claims, and may include other examples that occur to those skilled in the art. Such other examples are intended to be within the scope of the claims if they have structural elements that do not differ from the literal language of the claims, or if they include equivalent structural elements without substantial differences from the literal language of the claims.

1. A method for generating a magnetic resonance image, comprising:
generating a plurality of quantitative maps on the basis of a raw image, the raw image being obtained by executing a magnetic resonance scan sequence, and the magnetic resonance scan sequence having a plurality of scan parameters;
performing image conversion on the plurality of quantitative maps on the basis of the plurality of scan parameters to generate a first converted image and a second converted image;
generating a fused image of the first converted image and the second converted image; and
generating a plurality of quantitative weighted images on the basis of the fused image.

2. The method according to claim 1, wherein the generating a plurality of quantitative maps on the basis of a raw image comprises: generating a plurality of quantitative maps by performing deep learning processing on the raw image on the basis of a first deep learning network.

3. The method according to claim 1, wherein the plurality of quantitative weighted images are generated by performing deep learning processing on the fused image on the basis of a second deep learning network.

4. The method according to claim 1, wherein the fused image is generated by performing channel concatenation on the first converted image and the second converted image.

5. The method according to claim 1, wherein the plurality of quantitative maps comprise a quantitative T1 map, a quantitative T2 map, and a quantitative PD map, and the plurality of quantitative weighted images comprise a T1 weighted image, a T2 weighted image, and a T2 weighted-fluid attenuated inversion recovery image.

6. The method according to claim 1, wherein the plurality of scan parameters comprise echo time, repetition time, and inversion recovery time.

7. The method according to claim 6, wherein the performing image conversion on the plurality of quantitative maps on the basis of the plurality of scan parameters to generate a first converted image and a second converted image comprises:
generating the first converted image on the basis of a first formula, the first formula having the echo time and the plurality of quantitative maps as variables; and
generating the second converted image on the basis of a second formula, the second formula having the echo time, the repetition time, the inversion recovery time, and the plurality of quantitative maps as variables.

8. The method according to claim 1, wherein the raw image comprises at least one of a real image, an imaginary image, and a modular image generated on the basis of the real image and the imaginary image.

9. The method according to claim 1, wherein the raw image is obtained by executing a synthesized magnetic resonance scan sequence.

10. A computer-readable storage medium, comprising a stored computer program, wherein the method according to claim 1 is performed when the computer program is run.

11. A magnetic resonance imaging system, comprising:
a scanner, configured to execute a magnetic resonance scan sequence to generate a raw image, the magnetic resonance scan sequence having a plurality of scan parameters; and
an image processing module, comprising:
a first processing unit, configured to generate a plurality of quantitative maps on the basis of the raw image;
a conversion unit, configured to perform image conversion on the plurality of quantitative maps on the basis of the plurality of scan parameters to generate a first converted image and a second converted image;
an image fusion unit, configured to generate a fused image of the first converted image and the second converted image; and
a second processing unit, configured to generate a plurality of quantitative weighted images on the basis of the fused image.

12. The system according to claim 11, wherein the first processing unit is configured to perform deep learning processing on the raw image on the basis of a first deep learning network to generate the plurality of quantitative maps.

13. The system according to claim 11, wherein the second processing unit performs deep learning processing on the fused image on the basis of a second deep learning network to generate a plurality of quantitative weighted images.

14. The system according to claim 11, wherein the image fusion unit is configured to perform channel concatenation on the first converted image and the second converted image to generate the fused image.

15. The system according to claim 11, wherein the raw image is obtained by executing a synthesized magnetic resonance scan sequence.

16. A magnetic resonance imaging system, comprising:
a scanner, configured to execute a magnetic resonance scan sequence to generate a raw image, the magnetic resonance scan sequence having a plurality of scan parameters; and
an image processing module, configured to receive the raw image and perform the method for generating a magnetic resonance image according to claim 1.
